(19) United States
(12) Patent Application Publication
(10) Pub. No.: US 2024/0224708 A1
(43) Pub. Date: Jul. 4, 2024

(54) DISPLAY DEVICE

(71) Applicant: LG Display Co., Ltd., Seoul (KR)

(72) Inventors: Dongcheol CHOE, Incheon (KR); Inyeob NA, Seoul (KR)

(21) Appl. No.: 18/485,118

(22) Filed: Oct. 11, 2023

(30) Foreign Application Priority Data
Dec. 30, 2022 (KR) 10-2022-0191053

(51) Int. Cl. H10K 59/80; H10K 59/122; H10K 59/35

(52) U.S. Cl. CPC H10K 59/80518; H10K 59/122; H10K 59/35; H10K 59/80524

(57) ABSTRACT

According to an aspect of the present disclosure, a display device may include a substrate including a plurality of sub-pixels; an overcoating layer disposed on the substrate and having a protrusion portion where a trench is disposed and a base portion; an anode disposed to correspond to each of the plurality of sub-pixels and to cover the base portion and a part of the protrusion portion; a bank disposed on a part of the anode; an organic layer disposed on the anode and the bank; a cathode disposed on the organic layer; and a first trench electrode and a second trench electrode disposed on a side surface of the trench.

### CROSS-REFERENCE TO RELATED APPLICATIONS

This application claims the priority of Korean Patent Application No. 10-2022-0191053 filed on Dec. 30, 2022, in the Korean Intellectual Property Office, the disclosure of which is incorporated herein by reference.

### BACKGROUND

### Technical Field

The present disclosure relates to a display device, and more particularly, to a display device in which a luminance viewing angle may be improved and a leakage current may be minimized.

### Description of the Related Art

Recently, with the advancement of the information age, the field of display devices for visually displaying electrical information signals has grown rapidly. Thus, studies for developing performance, such as thinning, weight lightening, and low power consumption, of various display devices have continued.

Among various display devices, a light emitting display device is a self-emitting display device in which a separate light source is not needed, which is different from a liquid crystal display device. Therefore, the light emitting display device may be manufactured to be light and thin. Further, since the light emitting display device is driven at a low voltage, it is advantageous not only in terms of power consumption, but also in terms of color implementation, a response speed, a viewing angle, and a contrast ratio (CR). Therefore, it is expected to be utilized in various fields.

### BRIEF SUMMARY

An object to be achieved by the present disclosure is to provide a display device in which light efficiency of an organic light emitting element may be increased by using a side mirror type anode.

Another object to be achieved by the present disclosure is to provide a display device which may minimize a leakage current when it is driven.

Objects of the present disclosure are not limited to the above-mentioned objects, and other objects, which are not mentioned above, can be clearly understood by those skilled in the art from the following descriptions.

According to an aspect of the present disclosure, a display device includes a substrate including a plurality of sub-pixels. Also, the display device includes an overcoating layer disposed on the substrate and having a protrusion portion where a trench is disposed and a base portion. Namely, the overcoating layer has a protrusion portion, a trench and a base portion. Further, the display device includes an anode disposed to correspond to each of the plurality of sub-pixels and to cover the base portion and a part of the protrusion portion. Furthermore, the display device includes a bank disposed on a part of the anode. Moreover, the display device includes an organic layer disposed on the anode and the bank. Also, the display device includes a cathode disposed on the organic layer. Further, the display device includes a first trench electrode and a second trench electrode disposed on a side surface of the trench.

Other detailed matters of the exemplary embodiments are included in the detailed description and the drawings.

According to the present disclosure, it is possible to enhance light extraction efficiency of a light emitting display device and improve power consumption by using a side mirror type anode.

According to the present disclosure, a plurality of trench electrodes is disposed between a plurality of sub-pixels and a current is formed in the opposite direction to a leakage current. Thus, it is possible to minimize the leakage current.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device according to an embodiment of the present disclosure;

FIG. 2A is a plan view illustrating a plurality of trench electrodes and a controller of the display device according to an embodiment of the present disclosure;

FIG. 2B is an enlarged plan view of the display device of the region marked IIb of FIG. 1;

FIG. 3 is a cross-sectional view of the display device taken along a line III-III′ of FIG. 2B;

FIG. 4 is a timing diagram illustrating the operation of the plurality of trench electrodes when a plurality of sub-pixels of the display device according to an embodiment of the present disclosure emits light;

FIG. 5A is a plan view illustrating a plurality of trench electrodes and a controller of a display device according to another embodiment of the present disclosure;

FIG. 5B is an enlarged plan view illustrating a sub-pixel of the display device according to another embodiment of the present disclosure;

FIG. 5C is a cross-sectional view of the display device taken along a line Vc-Vc′ of FIG. 5B;

FIG. 5D is a cross-sectional view of the display device taken along a line Vd-Vd′ of FIG. 5B;

FIG. 5E is a cross-sectional view of the display device taken along a line Ve-Ve′ of FIG. 5B;

FIG. 6A is a plan view illustrating a plurality of trench electrodes and a controller of a display device according to yet another embodiment of the present disclosure;

FIG. 6B is an enlarged plan view illustrating a sub-pixel of the display device according to yet another embodiment of the present disclosure; and

FIG. 7 is a cross-sectional view of a display device according to still another embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, ‘consist of’ used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

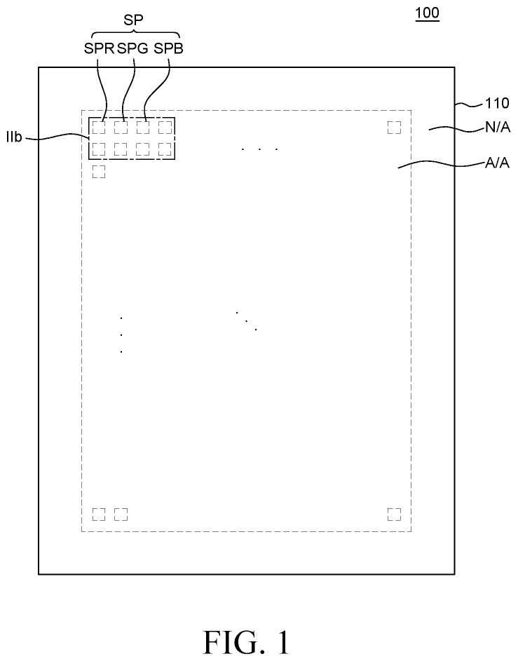

FIG. 1 is a plan view of a display device according to an embodiment of the present disclosure.

Referring to FIG. 1, a display device 100 includes a substrate 110. The display device 100 may be implemented as a top emission type display device, but is not limited thereto.

The substrate 110 serves to support and protect a variety of components of the display device 100. The substrate 110 may be made of glass or a plastic material having flexibility. When the substrate 110 is made of the plastic material, the substrate 110 may be made of, for example, polyimide (PI), but is not limited thereto.

The substrate 110 includes an active area A/A and a non-active area N/A.

The active area A/A is an area where images are displayed in the display device 100. In the active area A/A, a display element and various driving elements for driving the display element may be disposed. For example, the display element may be configured as a light emitting element including a first electrode, an organic layer, and a second electrode. Also, various driving elements, such as transistors, capacitors and lines, for driving the display element may be disposed in the active area A/A.

The active area A/A may include a plurality of sub-pixels SP. The sub-pixel SP is a minimum unit that configures a screen, and each of the plurality of sub-pixels SP may include a light emitting element and a driving circuit. The plurality of sub-pixels SP may emit light of different wavelengths, respectively. The plurality of sub-pixels may include first to third sub-pixels that emit light of different colors, respectively. For example, the plurality of sub-pixels SP may include a red sub-pixel SPR as a first sub-pixel, a green sub-pixel SPG as a second sub-pixel, and a blue sub-pixel SPB as a third sub-pixel. Further, the plurality of sub-pixels SP may further include a white sub-pixel.

The driving circuit of the sub-pixel SP is configured to control a driving of the light emitting element. For example, the driving circuit may be configured to include a transistor and a capacitor, but is not limited thereto.

The non-active area N/A is an area where no image is displayed and various components for driving the plurality of sub-pixels SP disposed in the active area A/A may be disposed. For example, a driver IC which supplies a signal for driving the plurality of sub-pixels SP, a flexible film or the like may be disposed in the non-active area N/A.

The non-active area N/A may be an area surrounding the active area A/A as illustrated in FIG. 1, but is not limited thereto. For example, the non-active area N/A may be an area extending from the active area A/A.

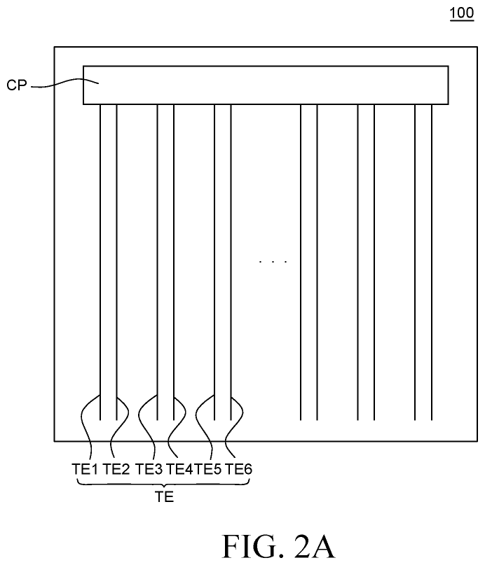

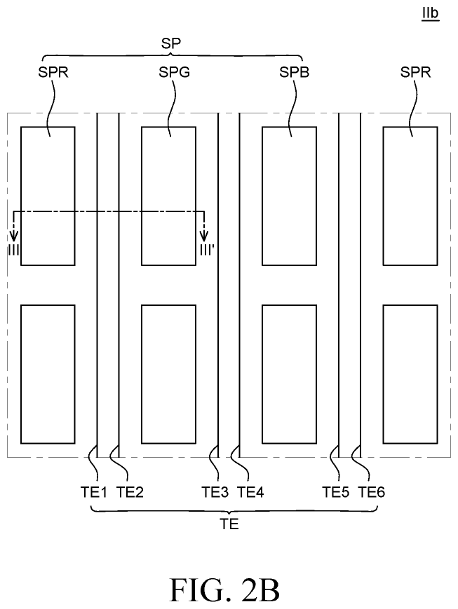

FIG. 2A is a plan view illustrating a plurality of trench electrodes and a controller of the display device according to an embodiment of the present disclosure. FIG. 2B is an enlarged plan view of the display device of the region marked IIb of FIG. 1. For the convenience of description, FIG. 2A illustrates only a controller CP and a plurality of trench electrodes TE among various components of the display device 100. Also, FIG. 2B illustrates only a plurality of sub-pixels SP and the plurality of trench electrodes TE.

Referring to FIG. 2A and FIG. 2B, the plurality of sub-pixels SP, the plurality of trench electrodes TE and the controller CP are disposed in the substrate 110.

The plurality of trench electrodes TE is disposed between the plurality of sub-pixels SP. Specifically, the plurality of trench electrodes TE is disposed between sub-pixels SP that emit light of different colors, respectively, and are disposed adjacent to each other. Each pair of the plurality of trench electrodes TE may be disposed between a plurality of sub-pixels. Thus, when a sub-pixel SP is disposed adjacent to n number of sub-pixels SP that emit light of different colors, respectively, 2n number of trench electrodes TE may be disposed with respect to the sub-pixel SP.

For example, as shown in FIG. 2B, if the plurality of sub-pixels SP includes the red sub-pixel SPR, the green sub-pixel SPG and the blue sub-pixel SPB, a first trench electrode TE1 and a second trench electrode TE2 are disposed between the red sub-pixel SPR and the green sub-pixel SPG. Also, a third trench electrode TE3 and a fourth trench electrode TE4 are disposed between the green sub-pixel SPG and the blue sub-pixel SPB. Further, a fifth trench electrode TE5 and a sixth trench electrode TE6 are disposed between the blue sub-pixel SPB and the red sub-pixel SPR.

Referring to FIG. 2B, a pair of trench electrodes TE is disposed between the plurality of sub-pixels SP and each of the trench electrodes TE is disposed adjacent to one of the plurality of sub-pixels SP. For example, the first trench electrode TE1 may be disposed between the red sub-pixel SPR and the green sub-pixel SPG so as to be adjacent to the red sub-pixel SPR. Also, the second trench electrode TE2 may be disposed between the red sub-pixel SPR and the green sub-pixel SPG so as to be adjacent to the green sub-pixel SPG.

The plurality of trench electrodes TE is connected to the controller CP. The controller CP transfers power to the trench electrodes TE. The controller CP is disposed on one end of the substrate 110 and disposed in the non-active area N/A. For example, the controller CP may be disposed in the driver IC or a timing controller disposed in the non-active area N/A, but the position of the controller CP is not limited thereto.

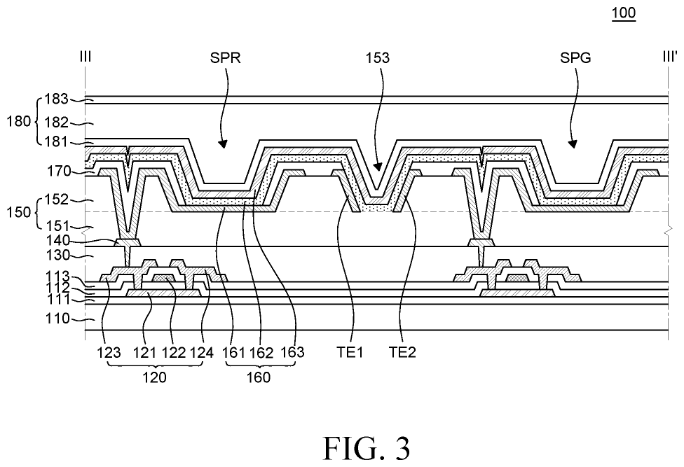

FIG. 3 is a cross-sectional view of the display device taken along a line III-III′ of FIG. 2B.

Referring to FIG. 3, the display device 100 includes the substrate 110, a transistor 120, a first overcoating layer 130, an auxiliary electrode 140, a second overcoating layer 150 and a light emitting element 160. Also, the display device 100 includes a plurality of trench electrodes TE1 and TE2, a bank 170 and an encapsulation unit 180.

A buffer layer 111 is disposed on the substrate 110. The buffer layer 111 may improve adhesion between layers formed on the buffer layer 111 and the substrate 110 and may block an alkali component or the like, flowing out of the substrate 110. The buffer layer 111 may be a single layer of silicon nitride (SiNx) or silicon oxide (SiOx), or a multilayer of silicon nitride (SiNx) or silicon oxide (SiOx), but is not limited thereto. The buffer layer 111 is not an essential component and may be omitted based on the type and material of the substrate 110 and the structure and type of the transistor 120.

The transistor 120 is disposed on the buffer layer 111. The transistor 120 may serve as a driving element to drive the light emitting element 160 disposed in the active area A/A. The transistor 120 includes an active layer 121, a gate electrode 122, a source electrode 123, and a drain electrode 124. The transistor 120 illustrated in FIG. 2 is a driving transistor and thin film transistor having a top gate structure in which the gate electrode 122 is disposed on the active layer 121. However, the present disclosure is not limited thereto. The transistor 120 may be implemented as a transistor having a bottom gate structure.

The active layer 121 is disposed on the buffer layer 111. When the transistor 120 is driven, a channel is formed in the active layer 121. The active layer 121 may be formed of an oxide semiconductor, amorphous silicon (a-Si), polycrystalline silicon (poly-Si), an organic semiconductor, or the like.

A gate insulating layer 112 is disposed on the active layer 121. The gate insulating layer 112 serves to electrically insulate the active layer 121 from the gate electrode 122 and may be made of an insulating material. For example, the gate insulating layer 112 may be a single layer of an inorganic material, such as silicon nitride (SiNx) or silicon oxide (SiOx), or a multilayer of silicon nitride (SiNx) or silicon oxide (SiOx), but is not limited thereto.

In the gate insulating layer 112, contact holes through which the source electrode 123 and the drain electrode 124 are in contact with a source region and a drain region, respectively, of the active layer 121 are formed. The gate insulating layer 112 may be formed on the entire surface of the substrate 110 as illustrated in FIG. 2, or may be patterned to have the same width as the gate electrode 122, but is not limited thereto.

The gate electrode 122 is disposed on the gate insulating layer 112. The gate electrode 122 is disposed on the gate insulating layer 112 so as to overlap a channel region of the active layer 121. The gate electrode 122 may be one of various metal materials, such as molybdenum (Mo), aluminum (Al), chromium (Cr), gold (Au), titanium (Ti), nickel (Ni), neodymium (Nd), and copper (Cu). Alternatively, the gate electrode 122 may be an alloy of two or more of them, or a multilayer thereof. However, the present disclosure is not limited thereto.

An interlayer insulating layer 113 is disposed on the gate electrode 122. For example, the interlayer insulating layer 113 may be a single layer of an inorganic material, such as silicon nitride (SiNx) or silicon oxide (SiOx), or a multilayer of silicon nitride (SiNx) or silicon oxide (SiOx), but is not limited thereto. In the interlayer insulating layer 113, contact holes through which the source electrode 123 and the drain electrode 124 are in contact with the source region and the drain region, respectively, of the active layer 121 are formed.

The source electrode 123 and the drain electrode 124 are disposed on the interlayer insulating layer 113. The source electrode 123 and the drain electrode 124 are disposed on the same layer to be spaced apart from each other. The source electrode 123 and the drain electrode 124 are electrically connected to the active layer 121 through the contact holes in the gate insulating layer 112 and the interlayer insulating layer 113. The source electrode 123 and the drain electrode 124 may be one of various metal materials, such as molybdenum (Mo), aluminum (Al), chromium (Cr), gold (Au), titanium (Ti), nickel (Ni), neodymium (Nd), and copper (Cu). Alternatively, the source electrode 123 and the drain electrode 124 may be an alloy of two or more of them, or a multilayer thereof. However, the present disclosure is not limited thereto.

In FIG. 3, only a driving transistor among various transistors 120 included in the display device 100 is illustrated, but other transistors such as a switching transistor may also be disposed.

The first overcoating layer 130 is disposed on the interlayer insulating layer 113 and the transistor 120. The first overcoating layer 130 is an insulating layer configured to protect the transistor 120 and planarize an upper portion of the transistor 120. A contact hole which exposes the source electrode 123 of the transistor 120 is formed in the first overcoating layer 130. FIG. 3 illustrates that the contact hole which exposes the source electrode 123 is formed in the first overcoating layer 130. However, the present disclosure is not limited thereto. For example, a contact hole which exposes the drain electrode 124 may be formed in the first overcoating layer 130.

The first overcoating layer 130 may be made of one of acrylic-based resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

In the meantime, a passivation layer may be further disposed under the first overcoating layer 130. The passivation layer covers the interlayer insulating layer 113 and the transistor 120. The passivation layer may be a single layer of silicon nitride (SiNx) or silicon oxide (SiOx), or a multilayer of silicon nitride (SiNx) or silicon oxide (SiOx), but it is not limited thereto.

The auxiliary electrode 140 is disposed on the first overcoating layer 130. The auxiliary electrode 140 may serve to electrically connect the transistor 120 to the light emitting element 160. The auxiliary electrode 140 is electrically connected to the source electrode 123 of the transistor 120 through the contact hole formed in the first overcoating layer 130. The auxiliary electrode 140 may be a single layer or a multilayer made of one of molybdenum (Mo), copper (Cu), titanium (Ti), aluminum (Al), chromium (Cr), gold (Au), nickel (Ni), and neodymium (Nd), or an alloy thereof.

The second overcoating layer 150 is disposed on the first overcoating layer 130. The second overcoating layer 150 is an insulating layer configured to planarize upper portions of the first overcoating layer 130 and the auxiliary electrode 140. A contact hole which exposes the auxiliary electrode 140 is formed in the second overcoating layer 150.

The second overcoating layer 150 may be made of one of acrylic-based resin, epoxy resin, phenol resin, polyamide-based resin, polyimide-based resin, unsaturated polyester-based resin, polyphenylene-based resin, polyphenylene sulfide-based resin, benzocyclobutene, and photoresist, but is not limited thereto.

The second overcoating layer 150 has a base portion 151 and a plurality of protrusion portions 152. As illustrated in FIG. 3, the base portion 151 and the protrusion portion 152 may be integrally formed. For example, the base portion 151 and the plurality of protrusion portions 152 may be made of the same material and may be simultaneously formed by the same process, for example, by a mask process. However, the present disclosure is not limited thereto.

The base portion 151 is disposed on the first overcoating layer 130. An upper surface of the base portion 151 is parallel to the substrate 110. Therefore, a step height caused by components disposed thereunder may be planarized by the base portion 151.

A plurality of protrusion portions 152 is disposed on the base portion 151. The plurality of protrusion portions 152 is integrally formed with the base portion 151 and protrudes from the base portion 151, but is not limited thereto. A trench 153 can formed between the protrusions. This can be done by etching a trench 153 in selected locations in the overcoating layer 150 that was previously formed at its full thickness. This will result in trenches 153 where the overcoating layer 150 is etched and protrusions 152 where it is not etched. Alternatively, the plurality of protrusion portions 152 may be separately formed from the base portion 151 in different embodiments. That is, the base portion 151 having a flat upper surface may be formed first and then, the plurality of protrusion portions 152 may be formed on the upper surface of the base portion 151. Each of the plurality of protrusion portions 152 may have a smaller upper surface than a lower surface, but is not limited thereto.

Each of the plurality of protrusion portions 152 has an upper surface and a side surface. The upper surface of the protrusion portion 152 is the uppermost surface of the protrusion portion 152 and may be substantially parallel to the base portion 151 or the substrate 110. The side surface of the protrusion portion 152 may serve to connect the upper surface of the protrusion portion 152 and the base portion 151. The side surface of the protrusion portion 152 may be inclined toward the base portion 151.

The light emitting element 160 and the plurality of trench electrodes TE1 and TE2 are disposed on the second overcoating layer 150.

The light emitting element 160 includes a first electrode 161 electrically connected to the source electrode 123 of the transistor 120 and an organic layer 162 disposed on the first electrode 161. Also, the light emitting element 160 includes a second electrode 163 disposed on the organic layer 162.

The first electrode 161 is disposed to correspond to each of the plurality of sub-pixels SP. The first electrode 161 is disposed to cover the base portion 151 and the plurality of protrusion portions 152. The first electrode 161 may be disposed along the shapes of the base portion 151 and the plurality of protrusion portions 152 of the planarization layer. Specifically, the first electrode 161 may be disposed on an upper surface of the base portion 151 on which any protrusion portion 152 is disposed, and side surfaces of the plurality of protrusion portions 152. That is, the first electrode 161 is disposed along the shapes of the base portion 151 and the protrusion portion 152. Also, the first electrode 161 may be formed on a part of upper surfaces of the plurality of protrusion portions 152.

The first electrode 161 may serve as an anode of the light emitting element 160. The first electrode 161 is electrically connected to the auxiliary electrode 140 through the contact hole formed in the second overcoating layer 150. The first electrode 161 may be electrically connected to the source electrode 123 of the transistor 120 through the auxiliary electrode 140. However, the first electrode 161 may also be configured to be electrically connected to the drain electrode 124 of the transistor 120 depending on the type of the transistor 120 and a design method of a driving circuit.

FIG. 3 illustrates that the first electrode 161 is a single layer, but the first electrode 161 may be configured as a multilayer. For example, the first electrode 161 may include a reflective layer that reflects light emitted from the organic layer 162 toward the second electrode 163 and a transparent conductive layer that supplies holes to the organic layer 162.

The reflective layer may be disposed on the second overcoating layer 150 to reflect light emitted from the light emitting element 160 upwardly. The light generated in the organic layer 162 of the light emitting element 160 may be emitted not only upwardly, but also laterally. The light that is laterally emitted may be directed to the inside of the display device 100 or trapped in the display device 100 due to total reflection, or may travel toward the display device 100 and then disappear. Therefore, the reflective layer may be disposed under the organic layer 162 to cover side portions of the plurality of protrusion portions 152 and may change a traveling direction of the light directed toward a side portion of the organic layer 162 to a front direction.

The reflective layer may be formed of a metal material, such as aluminum (Al), silver (Ag), copper (Cu), and a magnesium-silver alloy (Mg:Ag), but is not limited thereto.

The transparent conductive layer is disposed on the reflective layer. The transparent conductive layer may be made of a conductive material having a high work function to supply holes to the organic layer 162. For example, the transparent conductive layer may be made of a transparent conductive oxide, such as indium tin oxide (ITO), indium zinc oxide (IZO), indium tin zinc oxide (ITZO), zinc oxide (ZnO), and tin oxide (TO), but is not limited thereto.

The plurality of trench electrodes TE1 and TE2 is disposed on the same layer as the first electrode 161. The plurality of trench electrodes TE1 and TE2 is made of the same material as the first electrode 161. The plurality of trench electrodes TE1 and TE2 is disposed on side surfaces of trenches disposed in the second overcoating layer 150.

A pair of trench electrodes TE is disposed between the plurality of sub-pixels SP and each of the trench electrodes TE is disposed adjacent to one sub-pixel SP. For example, the first trench electrode TE1 may be disposed between the red sub-pixel SPR and the green sub-pixel SPG so as to be adjacent to the red sub-pixel SPR. Also, the second trench electrode TE2 may be disposed between the red sub-pixel SPR and the green sub-pixel SPG so as to be adjacent to the green sub-pixel SPG.

The organic layer 162 and the second electrode 163 are disposed between the first trench electrode TE1 and the second trench electrode TE2. Also, the first trench electrode TE1 and the second trench electrode TE2 are disposed adjacent to the organic layer 162.

The plurality of trench electrodes TE serves to suppress a transfer of a leakage current generated between the plurality of sub-pixels SP. For example, a pair of trench electrodes TE may form an electric field in the opposite direction to a transfer direction of the leakage current generated between the plurality of sub-pixels SP.

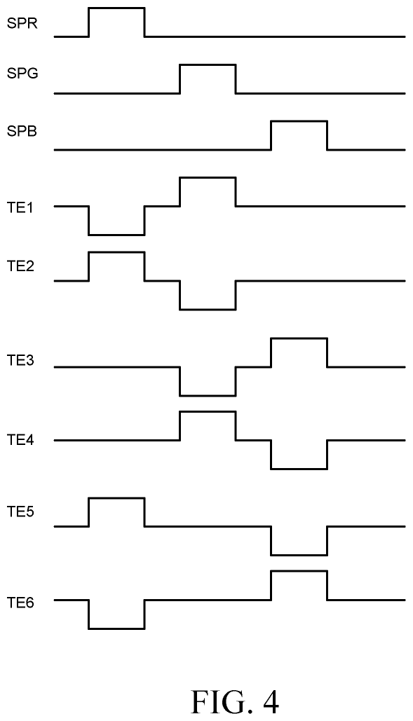

For example, as illustrated in FIG. 3, the first trench electrode TE1 and the second trench electrode TE2 may be disposed between the red sub-pixel SPR and the green sub-pixel SPG. In this case, when the red sub-pixel SPR is driven, the first trench electrode TE1 and the second trench electrode TE2 form an electric field in the opposite direction to a leakage current flowing to the adjacent green sub-pixel SPG. This will be described in detail with reference to FIG. 4.

The bank 170 is disposed on the second overcoating layer 150, the first electrode 161, and the plurality of trench electrodes TE. The bank 170 is an insulating layer configured to separate adjacent sub-pixels SP. The bank 170 may be disposed to form an opening region by opening a part of the first electrode 161. The bank 170 may form a non-opening region covering a part of the first electrode 161 and thus define an emission area and a non-emission area.

The bank 170 may be made of an inorganic material. For example, the bank 170 may be a single layer of silicon nitride (SiNx) or silicon oxide (SiOx), or a multilayer of silicon nitride (SiNx) or silicon oxide (SiOx), but is not limited thereto. The bank 170 may also be made of an organic material.

The organic layer 162 is disposed on the first electrode 161 and the bank 170. For example, the organic layer 162 is disposed on the first electrode 161 in an emission area EA and disposed on the bank 170 in a non-emission area NEA. The organic layer 162 may be disposed along the shapes of the first electrode 161 and the bank 170. The organic layer 162 includes an emission layer and a common layer.

The emission layer is an organic layer configured to emit light of a specific color. Different emission layers may be disposed in the plurality of sub-pixels SP, respectively. Alternatively, the same emission layer may be disposed throughout the plurality of sub-pixels SP. For example, if different emission layers are disposed in the plurality of sub-pixels SP, respectively, a red emission layer may be disposed in the red sub-pixel SPR and a green emission layer may be disposed in the green sub-pixel SPG. Also, a blue emission layer may be disposed in the blue sub-pixel SPB. If the same emission layer is formed throughout the plurality of sub-pixels SP, light emitted from the emission layer may be converted into light of various colors through a separate light conversion layer, a color filter, etc.

The common layer is an organic layer disposed to improve luminous efficiency of the emission layer. The common layer may be formed as the same layer throughout the plurality of sub-pixels SP. That is, the common layer for each of the plurality of sub-pixels SP may be made of the same material and may be simultaneously formed by the same process. The common layer may include a hole injection layer, a hole transport layer, an electron transport layer, an electron injection layer, and a charge generation layer, but is not limited thereto.

Meanwhile, the organic layer 162 may be configured by laminating a plurality of emission units each including an emission layer and configured to emit light. For example, each emission unit includes a hole injection layer, a hole transport layer, an emission layer, an electron transport layer, and an electron injection layer. Also, a charge generation layer configured to supply charges to a plurality of emission units is disposed between adjacent emission units. Therefore, the organic layer 162 may emit light which is a mixture of light emitted from the plurality of emission units. However, the present disclosure is not limited thereto.

The second electrode 163 is disposed on the organic layer 162. The second electrode 163 may be disposed along the shape of the organic layer 162. Since the second electrode 163 supplies electrons to the organic layer 162, it may be made of a conductive material having a low work function. The second electrode 163 may be a cathode of the light emitting element 160. The second electrode 163 may be made of a transparent conductive material, such as indium tin oxide (ITO) or indium zinc oxide (IZO), a metal alloy, such as MgAg, or an ytterbium (Yb) alloy, and may further include a metal-doped layer. However, the present disclosure is not limited thereto. In the meantime, although not illustrated in the drawings, a low potential power line may be electrically connected to the second electrode 163. Thus, the second electrode 163 may receive a low potential power signal.

The encapsulation unit 180 may be configured to protect the light emitting element 160, which is vulnerable to moisture, from being exposed to moisture. The encapsulation unit 180 may be formed on the light emitting element 160. The encapsulation unit 180 may block oxygen and moisture permeating into the display device 100 from the outside. For example, when the light emitting display device 100 is exposed to moisture or oxygen, a pixel shrinkage phenomenon in which the emission area is reduced may occur or a black spot may occur in the emission area. Accordingly, the encapsulation unit 180 protects the display device 100 by blocking oxygen and moisture. For example, the encapsulation unit 180 may have a structure in which an inorganic layer and an organic layer are alternately laminated, but is not limited thereto.

Referring to FIG. 3, the encapsulation unit 180 includes a first encapsulation layer 181, a foreign material cover layer 182, and a second encapsulation layer 183.

The first encapsulation layer 181 may be disposed on the second electrode 163 to suppress permeation of moisture or oxygen. The first encapsulation layer 181 may be made of an inorganic material, such as silicon nitride (SiNx), silicon oxynitride (SiNxOy), or aluminum oxide (AlyOz), but is not limited thereto. The first encapsulation layer 181 may be made of a material having a greater refractive index than the foreign material cover layer 182.

The foreign material cover layer 182 is disposed on the first encapsulation layer 181 to planarize a surface of the first encapsulation layer 181. Also, the foreign material cover layer 182 may cover foreign materials or particles that may be generated during a manufacturing process. The foreign material cover layer 182 may be made of an organic material, such as silicon oxycarbon (SiOxCz), acrylic or epoxy-based resin, etc., but is not limited thereto.

The second encapsulation layer 183 is disposed on the foreign material cover layer 182. Like the first encapsulation layer 181, the second encapsulation layer 183 may suppress permeation of moisture or oxygen. The second encapsulation layer 183 may be made of an inorganic material, such as silicon nitride (SiNx), silicon oxynitride (SiNxOy), silicon oxide (SiOx), or aluminum oxide (AlyOz), but is not limited thereto. The second encapsulation layer 183 may be made of either the same material as or a different material from the first encapsulation layer 181.

FIG. 4 is a timing diagram illustrating the operation of the plurality of trench electrodes when a plurality of sub-pixels of the display device according to an embodiment of the present disclosure emits light. FIG. 4 is a waveform diagram for describing electric potentials of a plurality of trench electrodes TE1, TE2, TE3, TE4, TE5 and TE6 when each of the sub-pixels SPR, SPG and SPB emits light.

Referring to FIG. 2B, the plurality of sub-pixels SP includes the red sub-pixel SPR, the green sub-pixel SPG, and the blue sub-pixel SPB. Also, the first trench electrode TE1 and the second trench electrode TE2 are disposed between the red sub-pixel SPR and the green sub-pixel SPG. Further, the third trench electrode TE3 and the fourth trench electrode TE4 are disposed between the green sub-pixel SPG and the blue sub-pixel SPB. Furthermore, the fifth trench electrode TE5 and the sixth trench electrode TE6 are disposed between the blue sub-pixel SPB and the red sub-pixel SPR.

The plurality of trench electrodes TE serves to suppress a transfer of a leakage current generated between the plurality of sub-pixels SP. For example, a pair of trench electrodes TE may form an electric field in the opposite direction to a transfer direction of the leakage current generated between the plurality of sub-pixels SP. Therefore, the plurality of trench electrodes TE may interrupt the flow of the leakage current and reduce the leakage current.

Referring to FIG. 4, when the red sub-pixel SPR among the red sub-pixel SPR and the green sub-pixel SPG adjacent to each other emits light, the first trench electrode TE1 may have a lower electric potential than the second trench electrode TE2. Therefore, an electric field is formed from the second trench electrode TE2 toward the first trench electrode TE1, and a transfer of a leakage current from the red sub-pixel SPR to the green sub-pixel SPG may be suppressed.

Further, when the green sub-pixel SPG among the red sub-pixel SPR and the green sub-pixel SPG adjacent to each other emits light, the first trench electrode TE1 may have a higher electric potential than the second trench electrode TE2. Therefore, an electric field is formed from the first trench electrode TE1 toward the second trench electrode TE2, and a transfer of a leakage current from the green sub-pixel SPG to the red sub-pixel SPR may be suppressed.

Referring to FIG. 4, when the green sub-pixel SPG among the green sub-pixel SPG and the blue sub-pixel SPB adjacent to each other emits light, the third trench electrode TE3 may have a lower electric potential than the fourth trench electrode TE4. Therefore, an electric field is formed from the fourth trench electrode TE4 toward the third trench electrode TE3, a transfer of a leakage current from the green sub-pixel SPG to the blue sub-pixel SPB may be suppressed.

Further, when the blue sub-pixel SPB among the green sub-pixel SPG and the blue sub-pixel SPB adjacent to each other emits light, the third trench electrode TE3 may have a higher electric potential than the fourth trench electrode TE4. Therefore, an electric field is formed from the third trench electrode TE3 toward the fourth trench electrode TE4, and a transfer of a leakage current from the blue sub-pixel SPB to the green sub-pixel SPG may be suppressed.

Referring to FIG. 4, when the blue sub-pixel SPB among the blue sub-pixel SPB and the red sub-pixel SPR adjacent to each other emits light, the fifth trench electrode TE5 may have a lower electric potential than the sixth trench electrode TE6. Therefore, an electric field is formed from the sixth trench electrode TE6 toward the fifth trench electrode TE5, and a transfer of a leakage current from the blue sub-pixel SPB to the red sub-pixel SPR may be suppressed.

Further, when the red sub-pixel SPR among the blue sub-pixel SPB and the red sub-pixel SPR adjacent to each other emits light, the fifth trench electrode TE5 may have a higher electric potential than the sixth trench electrode TE6. Therefore, an electric field is formed from the fifth trench electrode TE5 toward the sixth trench electrode TE6, and a transfer of a leakage current from the red sub-pixel SPR to the blue sub-pixel SPB may be suppressed.

The display device 100 according to an embodiment of the present disclosure may enhance light extraction efficiency of the light emitting element 160 by using the second overcoating layer 150 having the protrusion portion 152. For example, in the display device 100 according to an embodiment of the present disclosure, the second overcoating layer 150 is composed of the base portion 151 and the protrusion portion 152 protruding from the base portion 151. Also, the reflective layer of the first electrode 161 of the light emitting element 160 is disposed to cover the base portion 151 and at least a side surface of the protrusion portion 152. Therefore, light emitted at a low emission angle of the light emitted from the emission layer of the light emitting display device 100 may be extracted to the outside by the first electrode 161 disposed on the side of the protrusion portion 152. Therefore, in the display device 100 according to an embodiment of the present disclosure, the first electrode 161 disposed on the side of the second overcoating layer 150 serves as a side mirror. Thus, it is possible to extract light, which may be lost within the display device 100, to the outside, enhance light extraction efficiency, and improve power consumption.

In the display device 100 according to an embodiment of the present disclosure, the plurality of trench electrodes TE is disposed between the plurality of sub-pixels SP. Thus, it is possible to minimize a leakage current when the display device 100 is driven.

Specifically, in the display device 100 according to an embodiment of the present disclosure, the plurality of trench electrodes TE is disposed between the plurality of sub-pixels SP. When a sub-pixel SP emits light, a trench electrode TE adjacent to the sub-pixel SP emitting light has a relatively low electric potential. Thus, an electric field is formed in the opposite direction to a leakage current which is generated when the sub-pixel SP emits light. For example, as illustrated in FIG. 3, if the first trench electrode TE1 and the second trench electrode TE2 are disposed between the red sub-pixel SPR and the green sub-pixel SPG, the first trench electrode TE1 may have a lower electric potential than the second trench electrode TE2 when the red sub-pixel SPR emits light. Therefore, an electric field may be formed from the second trench electrode TE2 adjacent to the green sub-pixel SPG toward the first trench electrode TE1. Also, an electric field may be formed in the opposite direction to a leakage current flowing to the green sub-pixel SPG adjacent to the red sub-pixel SPR when the red sub-pixel SPR is driven. Accordingly, it is possible to interrupt the flow of the leakage current and reduce the leakage current. Therefore, in the display device 100 according to an embodiment of the present disclosure, the plurality of trench electrodes TE is disposed between the plurality of sub-pixels SP to minimize a leakage current when the display device 100 is driven.

Meanwhile, the plurality of trench electrodes TE may be configured according to various conditions in order for the emission layer of the organic layer 162 in contact with the plurality of trench electrodes TE not to emit light when the plurality of trench electrodes TE is driven.

First, the plurality of trench electrodes TE may have the same or lower electric potential than the second electrode 163 serving as a cathode. Thus, even if the plurality of trench electrodes TE is driven, a current does not flow from the plurality of trench electrodes TE to the second electrode 163. Therefore, when the plurality of trench electrodes TE is driven, the emission layer of the organic layer 162 may not emit light.

Herein, to suppress a breakdown in which a function of the light emitting element 160 is lost caused by an electric potential difference between the plurality of trench electrodes TE and the second electrode 163, the electric potential difference between the plurality of trench electrodes TE and the second electrode 163 may be lower than a breakdown voltage of the light emitting element 160.

If the organic layer 162 of the light emitting element 160 has a structure including a first emission layer, a second emission layer and a charge generation layer disposed between a plurality of emission layers, an electric potential difference between the plurality of trench electrodes TE and the charge generation layer may be lower than a turn-on voltage of the first emission layer. Thus, even if a current flows from the plurality of trench electrodes TE to the charge generation layer when the plurality of trench electrodes TE is driven, a voltage lower than the turn-on voltage of the first emission layer is applied to the first emission layer. Therefore, the first emission layer may not emit light.

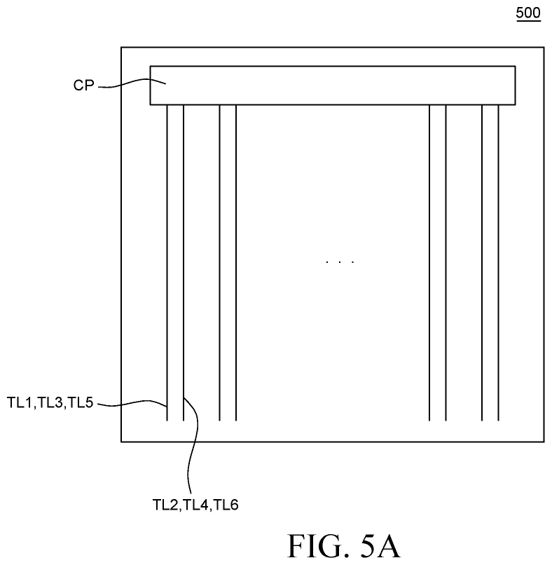

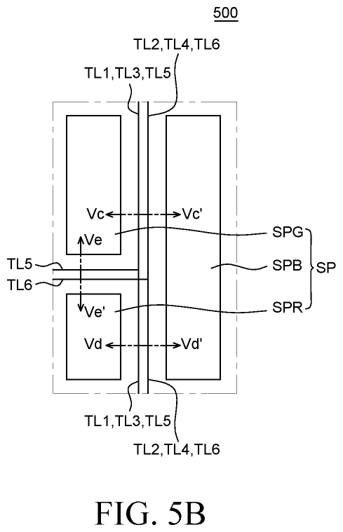

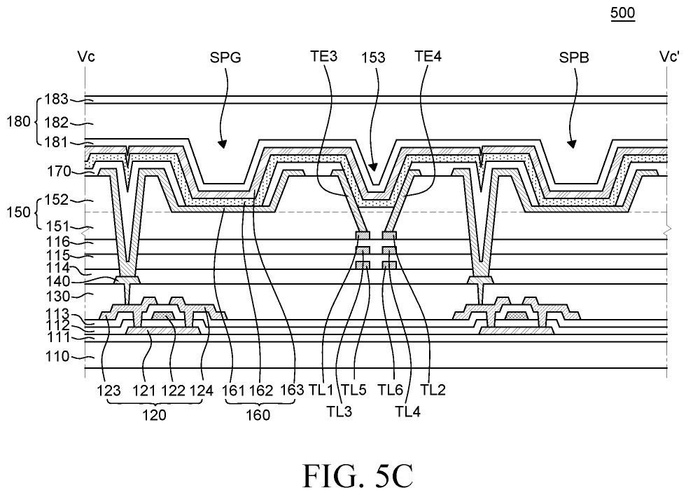

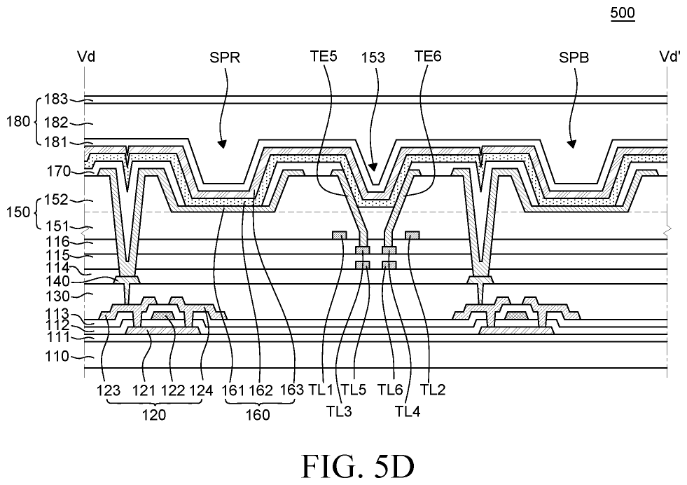

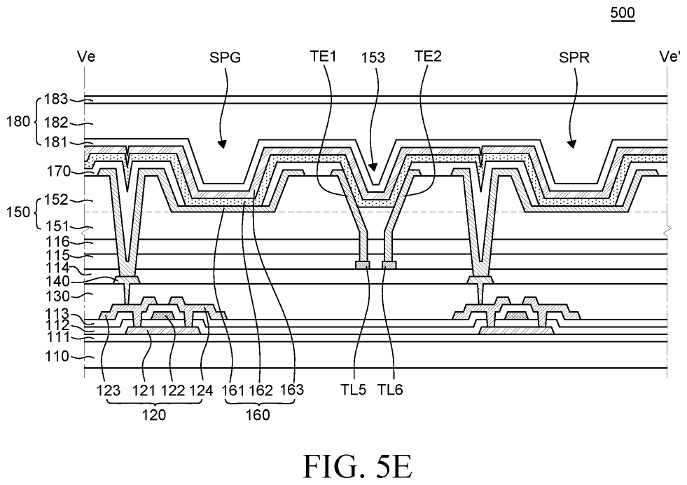

FIG. 5A is a plan view illustrating a plurality of trench electrodes and a controller of a display device according to another embodiment of the present disclosure. FIG. 5B is an enlarged plan view illustrating a sub-pixel of the display device according to another embodiment of the present disclosure. FIG. 5C is a cross-sectional view of the display device taken along a line Vc-Vc′ of FIG. 5B. FIG. 5D is a cross-sectional view of the display device taken along a line Vd-Vd′ of FIG. 5B. FIG. 5E is a cross-sectional view of the display device taken along a line Ve-Ve′ of FIG. 5B. A display device 500 illustrated in FIG. 5A through FIG. 5E is substantially the same as the display device 100 illustrated in FIG. 1 through FIG. 4 except the shapes of the plurality of sub-pixels and the addition of a plurality of trench lines TL1, TL2, TL3, TL4, TL5 and TL6. Therefore, redundant description thereof will be omitted.

Referring to FIG. 5A through FIG. 5E, the plurality of sub-pixels SP included in a sub-pixel SP has different sizes from each other. For example, the blue sub-pixel SPB may be disposed in a column, and the red sub-pixel SPR and the green sub-pixel SPG may be disposed together in an adjacent column. Also, the red sub-pixel SPR and the green sub-pixel SPG may be disposed alternately in the same column. It is described in the present disclosure that the plurality of sub-pixels SP includes the red sub-pixel SPR, the green sub-pixel SPG, and the blue sub-pixel SPB. However, the placement, number and color combinations of the plurality of sub-pixels SP may be variously changed depending on the design, but are not limited thereto.

The plurality of trench electrodes TE and the plurality of trench lines TL1, TL2, TL3, TL4, TL5 and TL6 connected to the plurality of trench electrodes TE, respectively, are disposed between the plurality of sub-pixels.

For example, the first trench electrode TE1 and the second trench electrode TE2 are disposed between the red sub-pixel SPR and the green sub-pixel SPG. Also, the third trench electrode TE3 and the fourth trench electrode TE4 are disposed between the green sub-pixel SPG and the blue sub-pixel SPB. Further, the fifth trench electrode TE5 and the sixth trench electrode TE6 are disposed between the blue sub-pixel SPB and the red sub-pixel SPR.

Meanwhile, as illustrated in FIG. 5A, some of the plurality of trench lines TL1, TL2, TL3, TL4, TL5 and TL6 may be disposed at the same position on the plane. Specifically, the first trench line TL1, the third trench line TL3, and the fifth trench line TL5 may be disposed at the same position on the plane. Also, the second trench line TL2, the fourth trench line TL4, and the sixth trench line TL6 may be disposed at the same position on the plane. Further, the plurality of trench lines TL1, TL2, TL3, TL4, TL5 and TL6 are disposed on three different layers. That is, some of the plurality of trench lines TL1, TL2, TL3, TL4, TL5 and TL6 connected to the plurality of trench electrodes TE, respectively, may be disposed at the same position on the plane and also disposed on three different layers so as not to be in contact with each other. Thus, the plurality of trench lines TL1, TL2, TL3, TL4, TL5 and TL6 may be configured to control the plurality of trench electrodes TE, respectively.

Referring to FIG. 5C through FIG. 5E, a plurality of inorganic insulating layers 114, 115 and 116 is disposed between the plurality of trench lines TL1, TL2, TL3, TL4, TL5 and TL6 disposed on three different layers. The inorganic insulating layers 114, 115 and 116 include the first inorganic insulating layer 114, the second inorganic insulating layer 115, and the third inorganic insulating layer 116. Each of the plurality of inorganic insulating layers 114, 115 and 116 may be a single layer of an inorganic material, such as silicon nitride (SiNx) or silicon oxide (SiOx), or a multilayer of silicon nitride (SiNx) or silicon oxide (SiOx), but is not limited thereto.

The first inorganic insulating layer 114 is disposed between the auxiliary electrode 140 and the first overcoating layer 130 and between the fifth trench electrode TE5 and the sixth trench electrode TE6. Also, the second inorganic insulating layer 115 is disposed between the fifth trench electrode TE5 and the sixth trench electrode TE6 and between the third trench line TL3 and the fourth trench line TL4. Further, the third inorganic insulating layer 116 is disposed between the third trench line TL3 and the fourth trench line TL4 and between the first trench line TL1 and the second trench line TL2. Thus, the plurality of inorganic insulating layers 114, 115 and 116 may electrically insulate the plurality of trench lines TL1, TL2, TL3, TL4, TL5 and TL6 from the other components.

Referring to FIG. 5C through FIG. 5E, lines connected to the first trench electrode TE1 and the second trench electrode TE2 are disposed on the same layer. Also, lines connected to the third trench electrode TE3 and the fourth trench electrode TE4 are disposed on the same layer. Further, lines connected to the fifth trench electrode TE5 and the sixth trench electrode TE6 are disposed on the same layer. For example, the fifth trench line TL5 and the sixth trench line TL6 connected to the first trench electrode TE1 and the second trench electrode TE2 are disposed on the same layer. Also, the first trench line TL1 and the second trench line TL2 connected to the third trench electrode TE3 and the fourth trench electrode TE4 are disposed on the same layer. Further, the third trench line TL3 and the fourth trench line TL4 connected to the fifth trench electrode TE5 and the sixth trench electrode TE6 are disposed on the same layer.

In the display device 500 according to another embodiment of the present disclosure, the plurality of trench electrodes TE is disposed between the plurality of sub-pixels SP. Thus, it is possible to minimize a leakage current when the display device 500 is driven.

Specifically, in the display device 500 according to another embodiment of the present disclosure, the plurality of trench electrodes TE is disposed between the plurality of sub-pixels SP. When a sub-pixel SP emits light, a trench electrode TE adjacent to the sub-pixel SP emitting light has a relatively low electric potential. Thus, an electric field is formed in the opposite direction to a leakage current which is generated when the sub-pixel SP emits light. For example, as illustrated in FIG. 5B and FIG. 5C, if the third trench electrode TE3 and the fourth trench electrode TE4 are disposed between the green sub-pixel SPG and the blue sub-pixel SPB, the third trench electrode TE3 may have a lower electric potential than the fourth trench electrode TE4 when the green sub-pixel SPG emits light. Therefore, an electric field may be formed from the fourth trench electrode TE4 adjacent to the blue sub-pixel SPB toward the third trench electrode TE3. Also, an electric field may be formed in the opposite direction to a leakage current flowing to the blue sub-pixel SPB adjacent to the green sub-pixel SPG when the green sub-pixel SPG is driven. Accordingly, it is possible to interrupt the flow of the leakage current and reduce the leakage current. Therefore, in the display device 500 according to another embodiment of the present disclosure, the plurality of trench electrodes TE is disposed between the plurality of sub-pixels SP to minimize a leakage current when the display device 500 is driven.

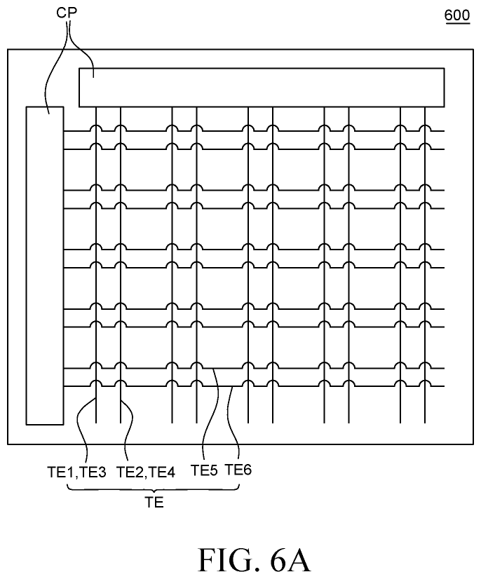

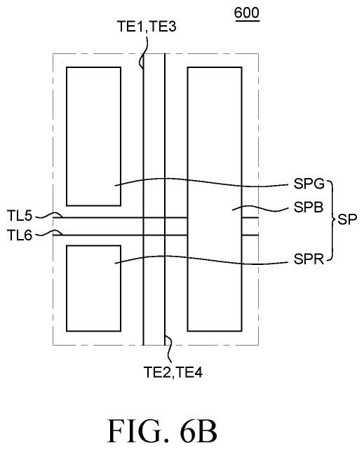

FIG. 6A is a plan view illustrating a plurality of trench electrodes and a controller of a display device according to yet another embodiment of the present disclosure. FIG. 6B is an enlarged plan view illustrating a sub-pixel of the display device according to yet another embodiment of the present disclosure. A display device 600 illustrated in FIG. 6 is substantially the same as the display device 500 illustrated in FIG. 5A through FIG. 5E except the addition of the controller CP. Therefore, redundant description thereof will be omitted.

Referring to FIG. 6A, a plurality of controllers CP is disposed on the substrate 110. One of the controllers CP is connected to the first trench electrode TE1, the second trench electrode TE2, the third trench electrode TE3, and the fourth trench electrode TE4. The other controller is connected to the fifth trench electrode TE5 and the sixth trench electrode TE6.

Some of the plurality of trench electrodes TE are disposed to intersect each other. Specifically, the fifth trench electrode TE5 and the sixth trench electrode TE6 may extend in a direction perpendicular to the first trench electrode TE1, the second trench electrode TE2, the third trench electrode TE3, and the fourth trench electrode TE4. Thus, the fifth trench electrode TE5 and the sixth trench electrode TE6 may intersect the first trench electrode TE1, the second trench electrode TE2, the third trench electrode TE3, and the fourth trench electrode TE4.

Referring to FIG. 6B, the plurality of sub-pixels SP included in a sub-pixel SP has different sizes from each other. For example, the blue sub-pixel SPB may be disposed in a column, and the red sub-pixel SPR and the green sub-pixel SPG may be disposed together in an adjacent column. Also, the red sub-pixel SPR and the green sub-pixel SPG may be disposed alternately in the same column. However, it is described in the present disclosure that the plurality of sub-pixels SP includes the red sub-pixel SPR, the green sub-pixel SPG, and the blue sub-pixel SPB. However, the placement, number and color combinations of the plurality of sub-pixels SP may be variously changed depending on the design, but are not limited thereto.

Referring to FIG. 6A and FIG. 6B, in the display device 600 according to yet another embodiment of the present disclosure, some of the plurality of trench electrodes TE may be disposed to intersect each other and disposed on different layers. Thus, these trench electrodes TE may not electrically interfere with each other. Specifically, the fifth trench electrode TE5 and the sixth trench electrode TE6 may be disposed on different layers from the first trench electrode TE1, the second trench electrode TE2, the third trench electrode TE3, and the fourth trench electrode TE4. Thus, the fifth trench electrode TE5 and the sixth trench electrode TE6 may be disposed not to interfere with the first trench electrode TE1, the second trench electrode TE2, the third trench electrode TE3, and the fourth trench electrode TE4.

In the display device 600 according to yet another embodiment of the present disclosure, the plurality of trench electrodes TE is disposed between the plurality of sub-pixels SP. Thus, it is possible to minimize a leakage current when the display device 600 is driven.

Specifically, in the display device 600 according to yet another embodiment of the present disclosure, the plurality of trench electrodes TE is disposed between the plurality of sub-pixels SP. When a sub-pixel SP emits light, a trench electrode TE adjacent to the sub-pixel SP emitting light has a relatively low electric potential. Thus, an electric field is formed in the opposite direction to a leakage current which is generated when the sub-pixel SP emits light. For example, as illustrated in FIG. 6B, if the third trench electrode TE3 and the fourth trench electrode TE4 are disposed between the green sub-pixel SPG and the blue sub-pixel SPB, the third trench electrode TE3 may have a lower electric potential than the fourth trench electrode TE4 when the green sub-pixel SPG emits light. Therefore, an electric field may be formed from the fourth trench electrode TE4 adjacent to the blue sub-pixel SPB toward the third trench electrode TE3. Also, an electric field may be formed in the opposite direction to a leakage current flowing to the blue sub-pixel SPB adjacent to the green sub-pixel SPG when the green sub-pixel SPG is driven. Accordingly, it is possible to interrupt the flow of the leakage current and reduce the leakage current. Therefore, in the display device 600 according to yet another embodiment of the present disclosure, the plurality of trench electrodes TE is disposed between the plurality of sub-pixels SP to minimize a leakage current when the display device 600 is driven.

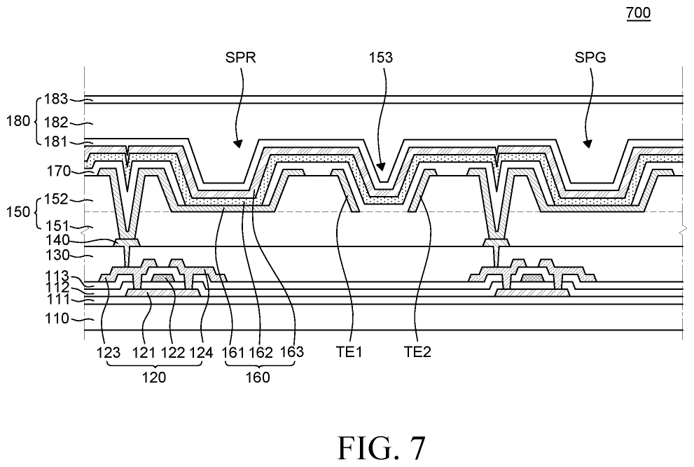

FIG. 7 is a cross-sectional view of a display device according to still another embodiment of the present disclosure. A display device 700 illustrated in FIG. 7 is substantially the same as the display device 100 illustrated in FIG. 1 through FIG. 4 except that the bank 170 is disposed between the plurality of trench electrodes TE and the organic layer 162. Therefore, redundant description thereof will be omitted.

Referring to FIG. 7, the bank 170 is disposed between the plurality of trench electrodes TE and the organic layer 162. Thus, the organic layer 162 may be insulated from the plurality of trench electrodes TE by the bank 170 and configured not to emit light when the plurality of trench electrodes TE is driven.

For example, as illustrated in FIG. 7, when the red sub-pixel SPR among the red sub-pixel SPR and the green sub-pixel SPG adjacent to each other emits light, the first trench electrode TE1 may have a lower electric potential than the second trench electrode TE2. Therefore, an electric field is formed from the second trench electrode TE2 toward the first trench electrode TE1, and a transfer of a leakage current from the red sub-pixel SPR to the green sub-pixel SPG may be suppressed.

The exemplary embodiments of the present disclosure can also be described as follows:

According to an aspect of the present disclosure, a display device may include a substrate including a plurality of sub-pixels; an overcoating layer disposed on the substrate and having a protrusion portion where a trench is disposed and a base portion; an anode disposed to correspond to each of the plurality of sub-pixels and to cover the base portion and a part of the protrusion portion; a bank disposed on a part of the anode; an organic layer disposed on the anode and the bank; a cathode disposed on the organic layer; and a first trench electrode and a second trench electrode disposed on a side surface of the trench.

The organic layer and the cathode may be disposed between the first trench electrode and the second trench electrode in the trench.

The first trench electrode and the second trench electrode may be in contact with the organic layer.

The first trench electrode may have a lower electric potential than the second trench electrode.

The first trench electrode and the second trench electrode may have the same or lower electric potential than the cathode.

The display device may further comprise a plurality of light emitting elements each composed of the anode, the organic layer, and the cathode.

An electric potential difference between the first and second trench electrodes and the cathode may be lower than a breakdown voltage of the light emitting element.

The organic layer may include a first emission layer, a second emission layer, and a charge generation layer disposed between the first emission layer and the second emission layer.

An electric potential difference between the first and second trench electrodes and the charge generation layer may be lower than a turn-on voltage of the first emission layer.

The bank, the organic layer, and the cathode may be disposed between the first trench electrode and the second trench electrode in the trench.

The bank may be disposed between the first and second trench electrodes and the organic layer.

The first trench electrode may have a lower electric potential than the second trench electrode.

A voltage equal to or lower than an electric potential of the cathode may be applied to the first trench electrode and the second trench electrode.

The plurality of sub-pixels may include a first sub-pixel and a second sub-pixel that emit light of different colors, respectively and may be disposed adjacent to each other.

The first trench electrode may be disposed between the first sub-pixel and the second sub-pixel so as to be adjacent to the first sub-pixel.

The second trench electrode may be disposed between the first sub-pixel and the second sub-pixel so as to be adjacent to the second sub-pixel.

When the first sub-pixel among the first sub-pixel and the second sub-pixel emits light, the first trench electrode may have a lower electric potential than the second trench electrode.

When the second sub-pixel among the first sub-pixel and the second sub-pixel emits light, the first trench electrode may have a higher electric potential than the second trench electrode.

The plurality of sub-pixels may include first to third sub-pixels that emit light of different colors, respectively.

The first trench electrode and the second trench electrode may be disposed between the first sub-pixel and the second sub-pixel.

A third trench electrode and a fourth trench electrode may be disposed between the second sub-pixel and the third sub-pixel.

A fifth trench electrode and a sixth trench electrode may be disposed between the third sub-pixel and the first sub-pixel.

The first to sixth trench electrodes may be disposed on three different layers.

Lines connected to the first trench electrode and the second trench electrode may be disposed on the same layer.

Lines connected to the third trench electrode and the fourth trench electrode may be disposed on the same layer.

Lines connected to the fifth trench electrode and the sixth trench electrode may be disposed on the same layer.

The first trench electrode and the second trench electrode may be made of the same material as the anode.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a plurality of sub-pixels;
an overcoating layer disposed on the substrate, the overcoating layer having a protrusion portion, a trench and a base portion;
an anode disposed to correspond to each of the plurality of sub-pixels and to cover the base portion and a part of the protrusion portion;
a bank disposed on a part of the anode;
an organic layer disposed on the anode and the bank;
a cathode disposed on the organic layer; and
a first trench electrode and a second trench electrode disposed on a side surface of the trench.

2. The display device according to claim 1, wherein the organic layer and the cathode are disposed between the first trench electrode and the second trench electrode in the trench, and
the first trench electrode and the second trench electrode are in contact with the organic layer.

3. The display device according to claim 2, wherein the first trench electrode has a lower electric potential than the second trench electrode.

4. The display device according to claim 3, wherein the first trench electrode and the second trench electrode have the same or lower electric potential than the cathode.

5. The display device according to claim 3, further comprising:
a plurality of light emitting elements each composed of the anode, the organic layer, and the cathode,
wherein an electric potential difference between the first and second trench electrodes and the cathode is lower than a breakdown voltage of the light emitting element.

6. The display device according to claim 2, wherein the organic layer includes a first emission layer, a second emission layer, and a charge generation layer disposed between the first emission layer and the second emission layer, and
an electric potential difference between the first and second trench electrodes and the charge generation layer is lower than a turn-on voltage of the first emission layer.

7. The display device according to claim 1, wherein the bank, the organic layer, and the cathode are disposed between the first trench electrode and the second trench electrode in the trench,
the bank is disposed between the first and second trench electrodes and the organic layer, and
the first trench electrode has a lower electric potential than the second trench electrode.

8. The display device according to claim 7, wherein a voltage equal to or lower than an electric potential of the cathode is applied to the first trench electrode and the second trench electrode.

9. The display device according to claim 1, wherein the plurality of sub-pixels includes a first sub-pixel and a second sub-pixel that emit light of different colors, respectively and are disposed adjacent to each other,
the first trench electrode is disposed between the first sub-pixel and the second sub-pixel so as to be adjacent to the first sub-pixel, and
the second trench electrode is disposed between the first sub-pixel and the second sub-pixel so as to be adjacent to the second sub-pixel.

10. The display device according to claim 9, wherein when the first sub-pixel among the first sub-pixel and the second sub-pixel emits light, the first trench electrode has a lower electric potential than the second trench electrode.

11. The display device according to claim 9, wherein when the second sub-pixel among the first sub-pixel and the second sub-pixel emits light, the first trench electrode has a higher electric potential than the second trench electrode.

12. The display device according to claim 1, wherein the plurality of sub-pixels includes first to third sub-pixels that emit light of different colors, respectively,
the first trench electrode and the second trench electrode are disposed between the first sub-pixel and the second sub-pixel,
a third trench electrode and a fourth trench electrode are disposed between the second sub-pixel and the third sub-pixel, and
a fifth trench electrode and a sixth trench electrode are disposed between the third sub-pixel and the first sub-pixel.

13. The display device according to claim 12, wherein the first to sixth trench electrodes are disposed on three different layers,
lines connected to the first trench electrode and the second trench electrode are disposed on the same layer,
lines connected to the third trench electrode and the fourth trench electrode are disposed on the same layer, and
lines connected to the fifth trench electrode and the sixth trench electrode are disposed on the same layer.

14. The display device according to claim 12, wherein the first trench electrode and the second trench electrode are made of the same material as the anode.
